(19) United States
(12) Patent Application Publication
(10) Pub. No.: US 2025/0132154 A1
(43) Pub. Date: Apr. 24, 2025

(54) METHODS AND APPARATUS FOR ANISOTROPIC FILM GROWTH, AND RELATED DEVICES

(71) Applicant: Applied Materials, Inc., Santa Clara, CA (US)

(72) Inventors: Chen-Ying WU, Santa Clara, CA (US); Abhishek DUBE, Fremont, CA (US); Zuoming ZHU, Sunnyvale, CA (US)

(21) Appl. No.: 18/491,584

(22) Filed: Oct. 20, 2023

(51) Int. Cl. H01L 21/02; C30B 25/16; C30B 29/52; H01L 27/088

(52) U.S. Cl. CPC H01L 21/0262; C30B 25/165; C30B 29/52; H01L 21/02532; H10D 84/834

(57) ABSTRACT

The present disclosure relates to semiconductor processing methods for anisotropic film growth. The method includes heating a substrate positioned in a processing chamber. The method includes flowing one or more process gases over the substrate. The one or more process gases include trichlorosilane (TCS) and hydrochloric acid. The method includes depositing one or more layers on one or more fins on the substrate. The deposition of the one or more layers includes forming the one or more layers at a first growth rate along a first dimension and a second growth rate along a second dimension, and the second growth rate is faster than the first growth rate.

### BACKGROUND

### Field

The present disclosure relates to semiconductor processing methods for anisotropic film growth, and more particularly, to one or more methods of forming fin field effect transistors (FinFET) and the resulting devices.

### Description of the Related Art

Epitaxial deposition processes are commonly used for depositing various semiconductor device structures. For example, the source and drain regions of a fin field effect transistor (FinFET) may be deposited via epitaxial processes. FinFET devices can include semiconductor fins on which the channel and source or drain regions for the transistor are formed thereover. A gate electrode is then formed over and alongside of a portion of the fin devices utilizing the advantage of the increased surface area of the channel and source or drain regions to produce faster, more reliable and better-controlled semiconductor transistor devices. Further advantages of FinFETs include reducing the short channel effect and providing higher current flow.

However, it can be difficult to control the merging of certain structures (such as source or drain structures, which can hinder device performance, hinder device applications, and affect throughput. Therefore, there is a need for improved methods of substrate processing.

### SUMMARY

The present disclosure relates to semiconductor processing methods for anisotropic film growth, and more particularly, to one or more methods of forming fin field effect transistors (FinFET) and the resulting devices. In one or more embodiments, the methods achieve anisotropic film growth for epitaxial deposition processes that include a dopant.

In one or more embodiments, a method of substrate processing applicable for semiconductor manufacturing is provided. The method includes heating a substrate positioned in a processing chamber. The method includes flowing one or more process gases over the substrate. The one or more process gases include trichlorosilane (TCS) and hydrochloric acid. The method includes depositing one or more layers on one or more fins on the substrate. The deposition of the one or more layers includes forming the one or more layers at a first growth rate along a first dimension and a second growth rate along a second dimension, and the second growth rate is faster than the first growth rate.

In one or more embodiments, a non-transitory storage medium including instructions that, when executed by a processor, will cause a plurality of operations to be performed is provided. The plurality of operations include flowing trichlorosilane (TCS) into a processing chamber at a first flow rate within a range of 100 sccm to 10,000 sccm. The plurality of operations include controlling a hydrogen gas into the processing chamber at a second flow rate that is 5 slm or less. The plurality of operations include controlling a pressure in the processing chamber to be less than 400 Torr.

In one or more embodiments, a device for semiconductor operations is provided. The device includes a substrate. The device includes one or more fins disposed on the substrate. The device includes a source or drain structure formed respectively on the one or more fins, the source or drain structure having a height that is larger than a width. The height is in a (100) plane and the width is in a (110) plane.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is a schematic block diagram view of a method of substrate processing, according to one or more embodiments.

FIGS. 3A-3C are a partial schematic side cross-sectional view of a device during a method, according to one or more embodiments.

FIG. 4 is a partial schematic side cross-sectional view of a device, according to one or more embodiments.

FIG. 5 is a schematic graphical view of a graph illustrating the effect of pressure on film growth rate, according to one or more embodiments.

### DETAILED DESCRIPTION

The present disclosure relates to semiconductor processing methods for anisotropic film growth, and more particularly, to one or more methods of forming fin field effect transistors (FinFET) and the resulting devices.

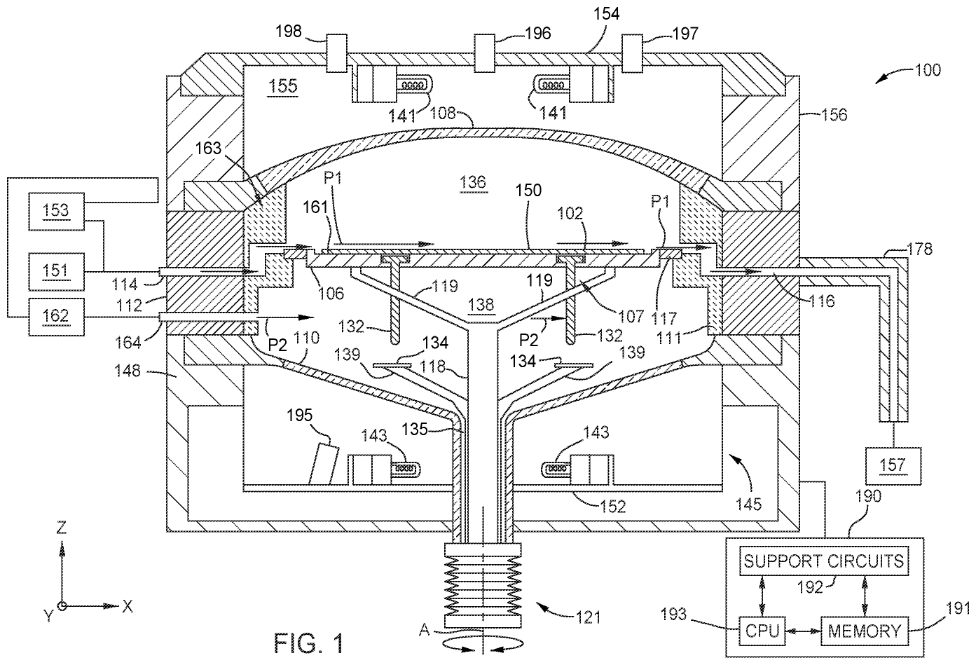

FIG. 1 is a partial schematic side cross-sectional view of a processing chamber, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163. In one or more embodiments, the upper volume 136 is a processing volume.

The internal volume has the substrate support 106 disposed therein. The substrate support 106 includes a top surface 161 on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P₂ supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P₁ include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the upper volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the upper volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the upper volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

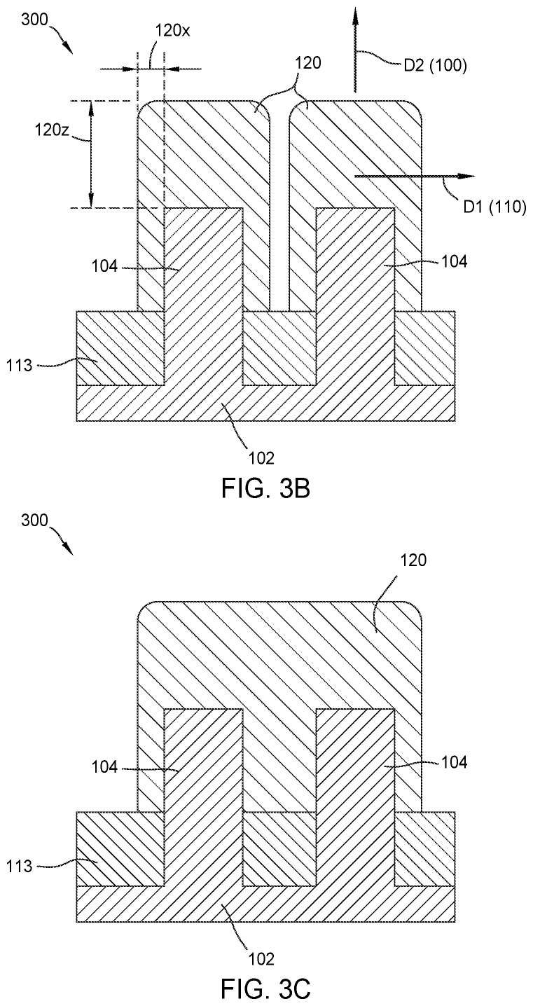

As shown, a controller 190 is in communication with the processing chamber 100 and is used to control processes and methods, such as the operations of the methods (for example the operations of the method 200 and/or the operations of FIGS. 3A-3C) described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 111, 163.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable storage medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters and operations are stored in the memory 191 as a software routine that is executed or invoked to turn the controller 190 into a specific purpose controller to control the operations of the various chambers/modules described herein. The controller 190 is configured to conduct any of the operations described herein (for example the operations of the method 200 and/or the operations of FIGS. 3A-3C). The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control the deposition, the cleaning, the rotational position, the heating, and gas flow through the processing chamber 100 by providing an output to the controls for the sensor devices 195, 196, 197, 198, the gas sources 151, 153, 162 and/or flow controllers in fluid communication with the gas sources 151, 153, 162, the suction device 188, the upper heat sources 141, the lower heat sources 143, the motion assembly 121, and/or the exhaust pump 157.

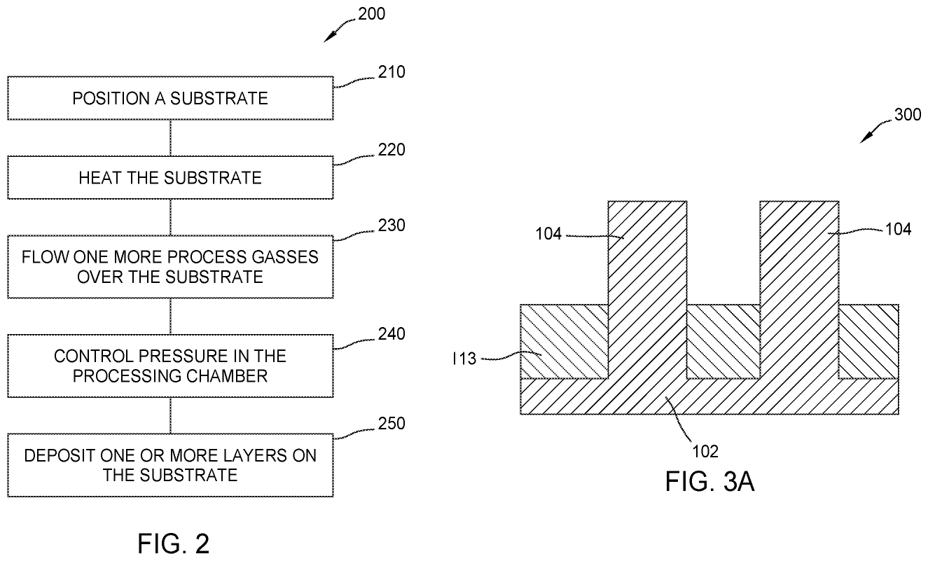

FIG. 2 is a schematic block diagram view of a method 200 of substrate processing, according to one or more embodiments. FIGS. 3A-3C are partial schematic side cross-sectional views of a device 300 during the method 200, according to one or more embodiments. The method 200 may be utilized to control the growth rate of source or drain structures 120 in the device 300. In one or more embodiments, the device 300 is a semiconductor device, such as a FinFET device. As shown in FIG. 3B, growth of the source or drain structures 120 is optimized by decreasing (e.g., minimizing) the growth rate in a first direction D1 (e.g., the (110) plane) and increasing (e.g., maximizing) the growth rate in a second direction D2 (e.g., the (100) plane) and. The subject matter described herein facilitates a “flush-fill” of the device 300 and a controlled merging of the source or drain structures 120. For example, an operator can control the source or drain structures 120 to not merge (as shown in FIG. 3B), or the operator can control the source or drain structures 120 to merge (as shown in FIG. 3C) at a certain time or under certain circumstances.

Operation 210 includes positioning a substrate 102 within a processing chamber 100. The substrate 102 may be the substrate 302 in FIG. 3A. The substrate 102 in operation 210 may have fins 104 with dielectric material 113 between the fins 104. In one or more embodiments, the substrate 102 may not have one or both of the dielectric material 113 and the fins 104, and the substrate 102 undergoes one or more processing steps to add the dielectric material 113 and/or the fins 104 between operation 210 and operation 220.

In operation 210, the substrate 102 may be positioned within the processing chamber 100 via a robotic arm, manual operation, or other means of positioning the substrate 102.

The substrate 102 may include any semiconductor material. In one or more embodiments, the substrate 102 includes silicon, such as monocrystalline silicon. In one or more embodiments, the substrate 102 includes a silicon film on a silicon on insulator (SOI) substrate. In one or more embodiment, the substrate 102 is a multi-layered substrate including materials such as one or more of silicon, silicon germanium, or germanium.

In one or more embodiments, the fins 104 include one or more of silicon, silicon germanium, or germanium.

In one or more embodiments, the dielectric material 113 include one or more of silicon dioxide, silicon nitride, silicon oxycarbonitride, or silicon oxynitride.

Operation 220 includes heating the substrate 102. The substrate 102 is heated to a temperature within a range of 200 degrees Celsius to 1,200 degrees Celsius. In one or more embodiments, the temperature is within a range of 600 degrees Celsius to 800 degrees Celsius, such as 650 degrees Celsius to 750 degrees Celsius, for example about 700 degrees Celsius.

Operation 230 includes flowing one or more process gases over the substrate 102. In one or more embodiments, the process gases are flowed over the substrate 102 simultaneously. In one or more embodiments, individual process gases are over the substrate 102 sequentially.

In one or more embodiments, the one or more process gases P in operation 230 include hydrogen gas (H₂), trichlorosilane (TCS), and phosphine (PH₃). Utilization of TCS as a reactant may result in a faster growth in the (100) plane relative to the growth in the (110) plane. In one or more embodiments, the one or more process gases include hydrochloric acid gas (HCl) to control selectivity of growth of the source or drain structures 120 on the fins 104 relative to the dielectric material 113.

In one or more embodiments, a flow rate of hydrogen gas is within a range of 0 slm to 10 slm, such as 0 slm to 5 slm or 0 slm to 3 slm. In one or more embodiments, a concentration of hydrogen gas in the one or more process gases is within a range of 0% to 40% by flow rate, such as within a range of 0% to 25%, such as 0% to 22% or 0% to 5%. In one or more embodiments, the concentration of hydrogen gas is less than 1%, such as about 0% (such that no hydrogen gas is flowed for the one or more process gases). Utilization of lower flow rates of hydrogen gas may result in a faster growth in the (100) plane relative to the decreased growth in the (110) plane.

In one or more embodiments, a flow rate of the TCS is within a range of 100 sccm to 10,000 sccm, such as 5,000 sccm to 10,000 sccm, for example 7,000 sccm to 9,000 sccm. In one or more embodiments, a flow rate of the hydrochloric acid is within a range of 10 sccm to 1000 sccm, such as 100 sccm to 200 sccm, for example 120 sccm to 140 sccm. In one or more embodiments, a flow rate of the phosphine is within a range of 1 sccm to 3,300 sccm, such as 2,500 sccm to 3,300 sccm, for example 2,700 sccm to 3,000 sccm. In one or more embodiments, the flow rate of the phosphine is within a range of 1 sccm to 3,000 sccm.

The present disclosure contemplates that the TCS, the phosphine, and/or the hydrochloric acid can flow in the form of gas.

Operation 240 includes controlling a pressure of the processing chamber 100. In one or more embodiments, the pressure of the processing chamber 100 is less than 400 Torr, such as within a range of 40 Torr to 300 Torr, for example 40 Torr to 150 Torr, such as 40 Torr to 100 Torr. In one or more embodiments, the pressure is 100 Torr or less, such as 85 Torr or less, for example 80 Torr or less. In one or more embodiments, the pressure is within a range of 70 Torr to 90 Torr, such as 75 Torr to 85 Torr. Utilization of a lower processing pressure may result in a faster growth in the (100) plane relative to the growth in the (110) plane.

In one or more embodiments, during operation 240, the pressure of the processing chamber 100 may be controlled by altering the respective flow(s) of the one or more process gases and operating the exhaust pump 157.

In operation 250, one or more layers are deposited on the substrate 102. The one or more layers can make up the source or drain structures 120 as shown in FIG. 3B. The one or more layers are formed at a first growth rate along a first dimension (e.g., in the first direction D1) and a second growth rate along a second dimension (e.g., in the second direction D2) The second growth rate is faster than the first growth rate. In one or more embodiments, the second growth rate is 40 Angstroms-per-minute or higher, such as 47 Angstroms-per-minute or higher. In one or more embodiments, method 200 may be arrested after the source or drain structures 120 achieve a height 120z and a width 120x as shown in FIG. 3B. After method 200, the device 300 may undergo other processing operations. The height 120z may be at least 200 Angstroms, such as at least 350 Angstroms, for example 480 Angstroms or higher. In one or more embodiments, the height 120z is within a range of 200 Angstroms to 600 Angstroms. The width 120x may range from zero to 600 Angstroms. The height 120z is larger than the width 120x. In one or more embodiments, a ratio of the height 120z to the width 120x is at least 1.2, for example 1.35 or higher, such as 50 or higher.

In one or more embodiments, the method 200 is continued after the source or drain structures 120 achieve the height 120z and the width 120x as shown in FIG. 3B. Continued operating of the method 200 results in increased amount of source or drain structures 120 growth, and the source or drain structures 120 merge together between the fins 104, as shown in FIG. 3C. In one or more embodiments, method 200 may be arrested after the source or drain structures 120 merge. In one or more embodiments, method 200 may be continued without arresting after the source or drain structures 120 merge. The present disclosure contemplates that the height 120z and the width 120x (including the associated values described above) can be achieved upon the merging shown in FIG. 3C. In one or more embodiments, the source or drain structures 120 have a rectangular cross-section in a plane extending transversely to the fins 104. In one or more embodiments, the source or drain structures 120 include (such as being formed of) silicon phosphide (SiP) or silicon germanium (SiGe). The source or drain structures 120 can fill in a trench between the fins 104, and/or the source or drain structures 120 can encapsulate portions of the fins 104 extending above the dielectric material 113.

In one or more embodiments, operation 220, operation 230, operation 240, and operation 250 occur simultaneously. In one or more embodiments, operation 220, operation 230, and operation 240 may commence in any order before and/or during operation 250.

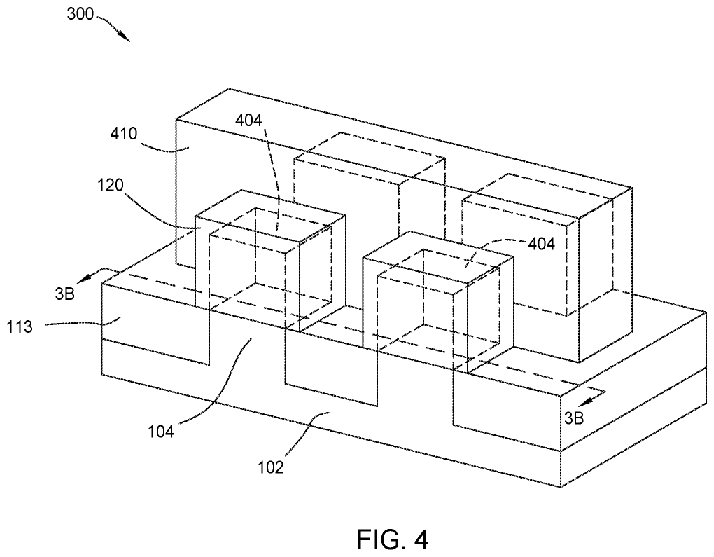

FIG. 4 is a schematic isometric view of a device 300, according to one or more embodiments. FIG. 3B is a cross-sectional view of the device 300 in FIG. 4, along Section 3B-3B shown in FIG. 4. FIG. 4 further includes a gate electrode 410 between the fins 104 and on the dielectric material 113. The present disclosure contemplates that sections 404 of the fins 104 can extend upwardly past an upper surface of the dielectric material 113 and into the source or drain structures 120. In one or more embodiments, a material (not shown for visual clarity purposes) is disposed between the source or drain structures 120 and the gate electrode 410. In one or more embodiments, the material is a gate dielectric. In one or more embodiments, the material includes one or more of silicon dioxide, silicon nitride, silicon carbonitride, or silicon oxycarbonitride. In one or more embodiments, the plurality of source or drain structures 120 include a plurality of source structures on one side of the gate electrode 410 and a plurality of drain structures on another side of the gate electrode 410.

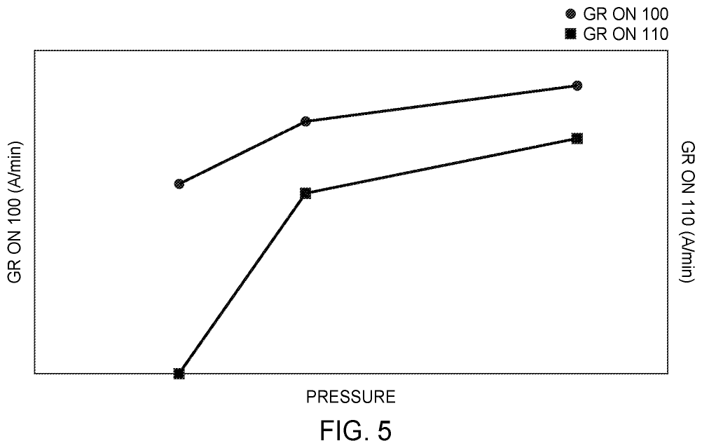

FIG. 5 is a schematic graphical view of a graph illustrating the effect of pressure on film growth rate, according to one or more embodiments. As shown in FIG. 5, decreasing the pressure in the processing chamber 100 results in decreased growth rate in the (110) plane. While decreasing the pressure in the processing chamber 100 can also marginally decreases the growth rate in the (100) plane, the magnitude of growth in the (100) plane is comparatively much larger than the growth rate in the (110) plane at lower pressures. Using subject matter described herein, the lower pressure can be used to control merging of deposited film (such as source or drain structures).

Benefits of the present disclosure include controlling merging of deposited film structures (such as SiP and/or SiGe films on fins in a FinFET semiconductor device); growing film at a faster rate in one direction (e.g., in the (100) plane) compared to another direction (e.g., in the (110) plane; enhanced device performance; and increased throughput. As an example, merging of the grown structures, when used, is more uniform and consistent.

It is contemplated that one or more aspects disclosed herein may be combined. As an example, one or more aspects, features, components, operations, and/or properties of the processing chamber 100, the method 200, the device 300 implementations shown in FIGS. 3A-3C, the device 300 implementation shown in FIG. 4, and/or the graph shown in FIG. 5 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A method of substrate processing applicable for semiconductor manufacturing, the method comprising:
heating a substrate positioned in a processing chamber;
flowing one or more process gases over the substrate, wherein the one or more process gases comprise:
trichlorosilane (TCS), and
a cleaning gas; and
depositing one or more layers on one or more fins on the substrate, the deposition of the one or more layers comprising:
forming the one or more layers at a first growth rate along a first dimension and a second growth rate along a second dimension, and the second growth rate is faster than the first growth rate.

2. The method of claim 1, wherein a concentration of hydrogen gas (H₂) in the one or more process gases is 25% or less by flow rate.

3. The method of claim 2, wherein the concentration of hydrogen gas (H₂) in the one or more process gases is 5% or less

4. The method of claim 1, wherein a flow rate of hydrogen gas in the one or more process gases is 5 slm or less.

5. The method of claim 1, further comprising controlling a pressure in the processing chamber, wherein the pressure is less than 400 Torr.

6. The method of claim 5, wherein the pressure is less than 100 Torr.

7. The method of claim 1, wherein the TCS is flowed at a flow rate within a range of 7,000 sccm to 9,000 sccm.

8. The method of claim 1, wherein the one or more process gases further comprise phosphine, and the phosphine is flowed at a flow rate within a range of 2,700 sccm to 3,000 sccm.

9. The method of claim 1, wherein the cleaning gas includes hydrogen and chlorine, the cleaning gas is flowed at a flow rate within a range of 100 sccm to 150 sccm.

10. A non-transitory storage medium comprising instructions that, when executed by a processor, will cause a plurality of operations to be performed, the plurality of operations comprising:
flowing trichlorosilane (TCS) into a processing chamber at a first flow rate within a range of 100 sccm to 10,000 sccm;
controlling a hydrogen gas into the processing chamber at a second flow rate that is 5 slm or less; and
controlling a pressure in the processing chamber to be less than 400 Torr.

11. The non-transitory storage medium of claim 10, wherein the plurality of operations further comprise:
flowing a gas including hydrogen and chlorine into the processing chamber at a third flow rate within a range of 100 sccm to 200 sccm.

12. The non-transitory storage medium of claim 10, wherein the pressure in the processing chamber is controlled to be less than 150 Torr.

13. The non-transitory storage medium of claim 10, wherein the pressure in the processing chamber is controlled to be less than or equal to 85 Torr.

14. The non-transitory storage medium of claim 10, wherein the first flow rate of TCS is within a range of 7,000 sccm to 9,000 sccm.

15. The non-transitory storage medium of claim 10, wherein the plurality of operations further comprise flowing phosphine into the processing chamber at a flow rate within a range of 2,500 sccm to 3,300 sccm.

16. A device for semiconductor operations, the device comprising:
a substrate;
one or more fins disposed on the substrate; and
a source or drain structure formed respectively on the one or more fins, the source or drain structure having a height that is larger than a width, wherein the height is in a (100) plane and the width is in a (110) plane.

17. The semiconductor of claim 16, wherein a ratio of the height to the width is at least 1.2.

18. The semiconductor of claim 16, wherein the substrate includes one or more of silicon, silicon germanium, or germanium.

19. The semiconductor of claim 16, wherein the fin includes one or more of silicon, silicon germanium, or germanium.

20. The semiconductor of claim 16, wherein the source or drain structure has a rectangular cross-section and is formed of silicon phosphide (SiP) or silicon germanium (SiGe).
